(19) United States
(12) Patent Application Publication
(10) Pub. No.: US 2026/0150428 A1
(43) Pub. Date: May 28, 2026

(54) IMAGE SENSOR INCLUDING BURIED INTERCONNECTIONS

(71) Applicant: Samsung Electronics Co., Ltd., Suwon-si (KR)

(72) Inventors: Minsung Kim, Suwon-si (KR); Sooyoung Kang, Suwon-si (KR); Jameyung Kim, Suwon-si (KR); Dongmo Im, Suwon-si (KR)

(21) Appl. No.: 19/391,483

(22) Filed: Nov. 17, 2025

(30) Foreign Application Priority Data
Nov. 22, 2024 (KR) 10-2024-0168117

(51) Int. Cl. H10F 39/00

(52) U.S. Cl. CPC H10F 39/811; H10F 39/807

(57) ABSTRACT

An image sensor includes a semiconductor substrate; a pixel isolation pattern disposed in the semiconductor substrate and defining a first pixel region and a second pixel region, in which the first pixel region includes a first photoelectric conversion region and a second photoelectric conversion region, spaced apart from each other in a first horizontal direction; a device isolation pattern disposed on a first surface of the semiconductor substrate and defining active regions; floating diffusion regions disposed adjacently to the first surface of the semiconductor substrate, in which the floating diffusion regions include a first floating diffusion region and a second floating diffusion region, respectively overlapping the first photoelectric conversion region and the second photoelectric conversion region in a vertical direction; and a buried interconnection portion buried in the semiconductor substrate and electrically connecting the first floating diffusion region and the second floating diffusion region to each other.

### CROSS-REFERENCE TO RELATED APPLICATION(S)

This application claims benefit of priority to Korean Patent Application No. 10-2024-0168117 filed on Nov. 22, 2024, in the Korean Intellectual Property Office, the disclosure of which is incorporated herein by reference in its entirety.

### BACKGROUND

An image sensor converts an optical image into an electrical signal. Recently, with the development of the computer industry and telecommunications industries, demand for image sensors with improved performance has been increasing in various fields such as a digital camera, a camcorder, a personal communication system (PCS), a game machine, a security camera, a medical micro camera, or the like. An example of an image sensor may include a charge-coupled device (CCD) and a CMOS image sensor. The CMOS image sensor may have a simple driving method, and may integrate a signal processing circuit into a single chip, enabling miniaturization of a product thereof. As demands for high performance, high speed, and/or multi-functionality in image sensors increase, a degree of integration of image sensors is increasing.

### SUMMARY

In general, the present disclosure is directed toward an image sensor including a buried interconnection portion, buried in a substrate by electrically connecting floating diffusion regions.

According to some implementations, the present disclosure is directed to an image sensor that includes a semiconductor substrate having first and second surfaces located opposite to each other; a pixel isolation pattern disposed in the semiconductor substrate and defining a first pixel region and a second pixel region, wherein the first pixel region includes a first photoelectric conversion region and a second photoelectric conversion region, spaced apart from each other in a first horizontal direction; a device isolation pattern disposed on the first surface of the semiconductor substrate and defining active regions; floating diffusion regions disposed adjacently to the first surface of the semiconductor substrate, wherein the floating diffusion regions include a first floating diffusion region and a second floating diffusion region, respectively overlapping the first photoelectric conversion region and the second photoelectric conversion region in a vertical direction; and a buried interconnection portion buried in the semiconductor substrate from the first surface of the semiconductor substrate, and electrically connecting the first floating diffusion region and the second floating diffusion region to each other.

According to some implementations, the present disclosure is directed to an image sensor that includes a semiconductor substrate having first and second surfaces located opposite to each other; a pixel isolation pattern disposed in the semiconductor substrate and defining pixel regions, wherein the pixel regions include photoelectric conversion regions disposed in the semiconductor substrate; a device isolation pattern disposed on the first surface of the semiconductor substrate and defining active regions; floating diffusion regions disposed adjacently to the first surface of the semiconductor substrate and overlapping the photoelectric conversion regions in a vertical direction; and a first buried interconnection portion electrically connecting four adjacent floating diffusion regions among the floating diffusion regions, wherein the semiconductor substrate is formed on the first surface and includes a first recess region exposing the floating diffusion regions, the first buried interconnection portion extends in the first recess region in a horizontal direction, and the first buried interconnection portion electrically connects the four adjacent floating diffusion regions among the floating diffusion regions to each other.

According to some implementations, the present disclosure is directed to an image sensor that includes a semiconductor substrate having first and second surfaces located opposite to each other; a pixel isolation pattern disposed in the semiconductor substrate and defining first to fourth pixel regions, wherein the first to fourth pixel regions include photoelectric conversion regions disposed in the semiconductor substrate; a device isolation pattern disposed on the first surface of the semiconductor substrate and defining active regions; a floating diffusion region disposed adjacently to the first surface of the semiconductor substrate and overlapping the photoelectric conversion regions in a vertical direction; a first buried interconnection portion electrically connecting four adjacent floating diffusion regions among the floating diffusion regions to each other; a second buried interconnection portion electrically connecting four adjacent floating diffusion regions among the floating diffusion regions to each other and spaced apart from the first buried interconnection portion in a first horizontal direction; and a buried conductive line electrically connecting the first buried interconnection portion and the second buried interconnection portion, and extending in the first horizontal direction, wherein the first buried interconnection portion is disposed between the first pixel region and the second pixel region, spaced apart from each other, in a second horizontal direction, intersecting the first horizontal direction, and the second buried interconnection portion is disposed between the third pixel region and the fourth pixel region respectively spaced apart from the first pixel region and the second pixel region in the first horizontal direction.

### BRIEF DESCRIPTION OF DRAWINGS

Example implementations will be more clearly understood from the following detailed description, taken in conjunction with the accompanying drawings.

FIG. 1 is an exploded perspective view illustrating an example of an image sensor according to some implementations.

FIG. 2 is an enlarged view of an example of a portion of the image sensor illustrated in FIG. 1 according to some implementations.

FIG. 3 is a vertical cross-sectional view taken along line A-A′ of the image sensor of FIG. 2 according to some implementations.

FIG. 4 is an enlarged view of an example of a portion of the image sensor illustrated in FIG. 2 according to some implementations.

FIG. 5 is a circuit diagram of an example of a unit pixel corresponding to each of the pixel regions of FIG. 4 according to some implementations.

FIG. 6 is a vertical cross-sectional view taken along line I-I′ of the pixel array illustrated in FIG. 4 according to some implementations.

FIG. 7 is a vertical cross-sectional view taken along line II-II′ of the pixel array illustrated in FIG. 4 according to some implementations.

FIG. 8 is a vertical cross-sectional view taken along line III-III′ of the pixel array illustrated in FIG. 4 according to some implementations.

FIG. 9 is a vertical cross-sectional view taken along line IV-IV′ of the pixel array illustrated in FIG. 4 according to some implementations.

FIG. 10 is a vertical cross-sectional view taken along line V-V′ of the pixel array illustrated in FIG. 4 according to some implementations.

FIG. 11 is a partial enlarged view of the pixel array illustrated in FIG. 10 according to some implementations.

FIG. 12 is a partial enlarged view of FIGS. 9 and 10 according to some implementations.

FIG. 13 is a perspective view illustrating examples of a buried interconnection portion and a buried conductive line according to some implementations.

FIG. 14 is a plan view of an example of an image sensor according to some implementations.

FIGS. 15 to 18 are vertical cross-sectional views of an example of an image sensor according to some implementations.

FIGS. 19A to 19F are cross-sectional views of processes illustrating an example of a method of manufacturing an image sensor according to some implementations.

### DETAILED DESCRIPTION

Hereinafter, example implementations will be explained in detail with reference to the accompanying drawings.

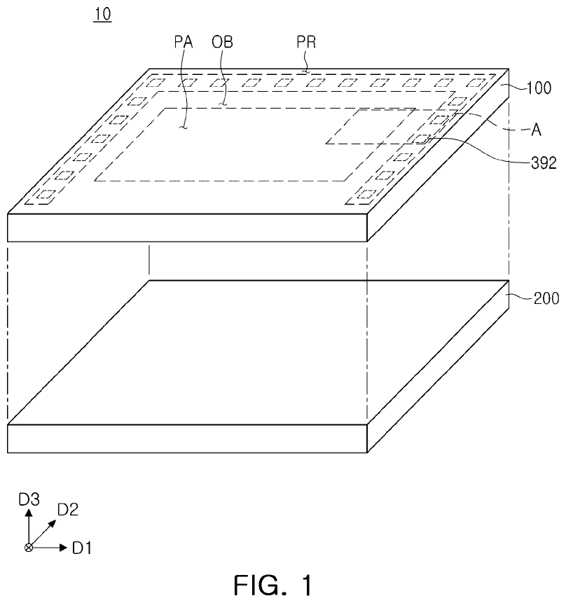

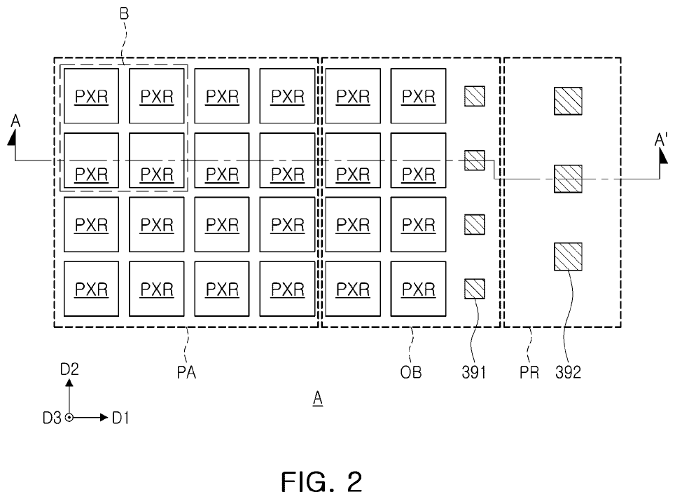

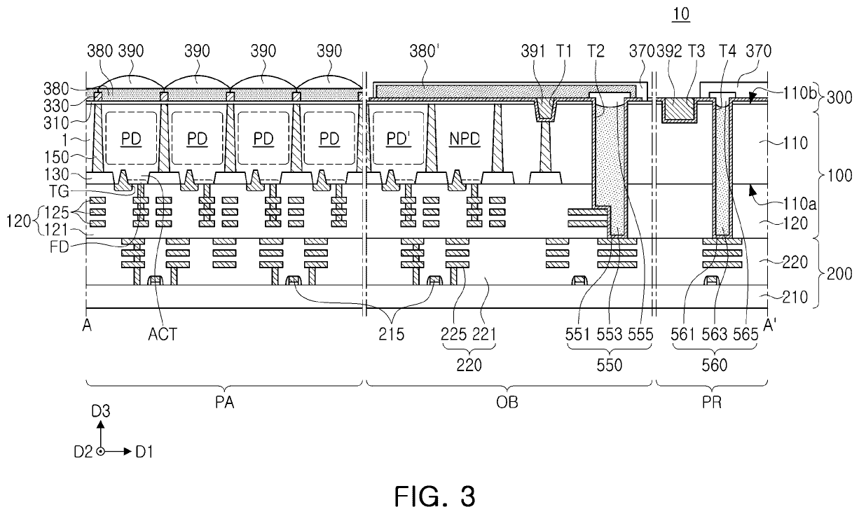

FIG. 1 is an exploded perspective view illustrating an example of an image sensor according to some implementations. FIG. 2 is an enlarged view of a portion of the image sensor illustrated in FIG. 1 according to some implementations. FIG. 3 is a vertical cross-sectional view taken along line A-A′ of the image sensor of FIG. 2 according to some implementations.

In FIGS. 1 to 3, an image sensor 10 may include a first substrate structure 100 and a second substrate structure 200, stacked and electrically connected to each other. The first substrate structure 100 may include a first substrate 110 having a pixel array region PA, a first interconnection structure 120 on a first surface 110a of the first substrate 110, and a light-transmitting structure 300 on a second surface 110b of the substrate 110. The second substrate structure 200 may include a second substrate 210 having an upper surface on which logic elements 215 are disposed, and a second interconnection structure 220 contacting the first interconnection structure 120 on the second substrate 210. In this case, the first substrate structure 100 may also be referred to as a ‘sensor chip,’ and the second substrate structure 200 may also be referred to as a ‘logic chip.’

The first substrate 110 may include a light-blocking region OB and a pad region PR, in addition to the pixel array region PA in plan view. The pixel array region PA may include a plurality of pixel regions PXR receiving light and generating an active signal. The plurality of pixel regions PXR may be disposed in a plurality of rows and a plurality of columns in the pixel array region PA.

The light-blocking region OB may be disposed, for example, around the pixel array region PA. The light-blocking region OB may include optical black pixels blocking light to generate an optical black signal. In some embodiments, dummy pixels may be disposed in the light-blocking region OB.

The pad region PR may be disposed around the light-blocking region OB. In some embodiments, the pad region PR may be disposed adjacently to an edge of the image sensor 10. Although the pad region PR is illustrated as being disposed along three sides of the image sensor 10 in the present embodiment, but in some implementations, the pad region PR may be disposed to surround two sides, or all sides. The pad region PR may include a plurality of pads (392) connecting to an external device, and may be configured to transmit and receive an electrical signal between the image sensor 10 and the external device.

In FIG. 3, the first substrate 110 may include a device isolation pattern 130 defining an active region ACT on the first surface 110a, and pixel circuit devices such as a vertical transfer gate TG on the active region ACT. A plurality of photoelectric conversion regions PD may be disposed in the first substrate 110.

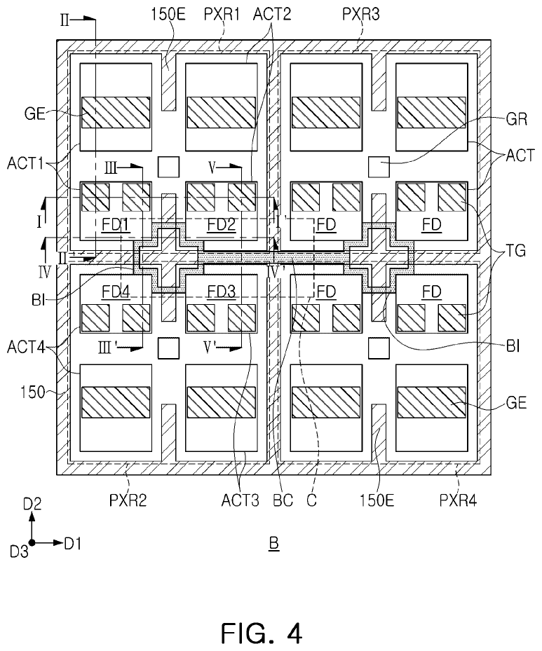

The image sensor 10 may be a back-side illumination (BSI) image sensor. The second surface 110b of the first substrate 110 may be provided as a light-receiving surface on which light is incident. The first substrate 110 may further include a pixel isolation pattern 150 defining the plurality of pixel regions PXR. The pixel isolation pattern 150 may be disposed to surround the photoelectric conversion regions PD included in the plurality of pixel regions PXR. As illustrated in FIG. 4, the pixel isolation pattern 150 may be disposed in a grid shape to separate the plurality of pixel regions PXR in plan view. The pixel isolation pattern 150 may penetrate at least a portion of the first substrate 110.

The first substrate 110 may be a semiconductor substrate. For example, the first substrate 110 may be a bulk silicon substrate or a silicon-on-insulator (SOI) substrate. In the present disclosure, the first substrate 110 may be referred to as a “semiconductor substrate.” As described above, the plurality of pixel regions PXR may be disposed in a planar manner (e.g., in a matrix) in the pixel array region PA including a first direction X and a second direction Y. Each of the pixel regions PXR may include at least one photoelectric conversion region PD disposed in the first substrate 110. The photoelectric conversion regions PD may generate charges in proportion to the amount of light incident from the outside. For example, the photoelectric conversion regions PD may be a photo diode, a photo transistor, a photo gate, a pinned photo diode, or an organic photo diode.

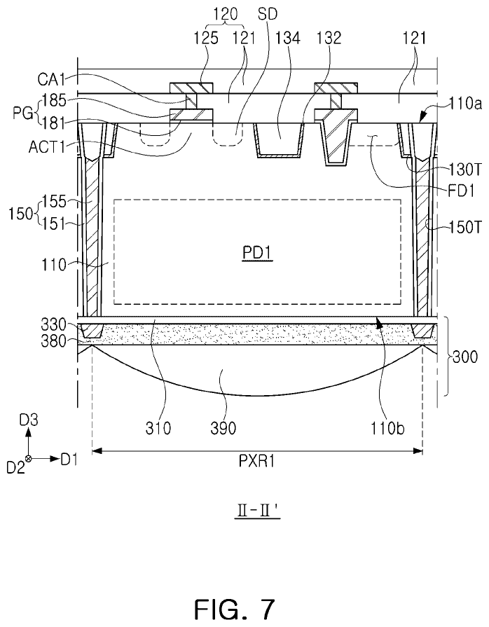

As described above, the first substrate 110 may include pixel circuit devices formed in the active region ACT of the first surface 110a. The pixel circuit devices may include a transfer gate TG and various circuit devices. The circuit devices may each include a gate “GE” (FIG. 7) and a source/drain “SD” (FIG. 7). The pixel circuit devices will be described in detail later with reference to FIGS. 4 to 10.

The photoelectric conversion regions PD may be disposed in the pixel array region PA provided as an active pixel, but some of the photoelectric conversion regions may be disposed in the light-blocking region OB. The photoelectric conversion regions disposed in the light-blocking region OB may include a first reference region PD′ configured identically to the photoelectric conversion regions PD, and a second reference region (dummy photoelectric conversion region NPD) not forming the photoelectric conversion region. In the light-blocking region OB, the first and second reference regions PD′ and NPD may be disposed in the first substrate 110, and may be separated by the pixel isolation pattern 150.

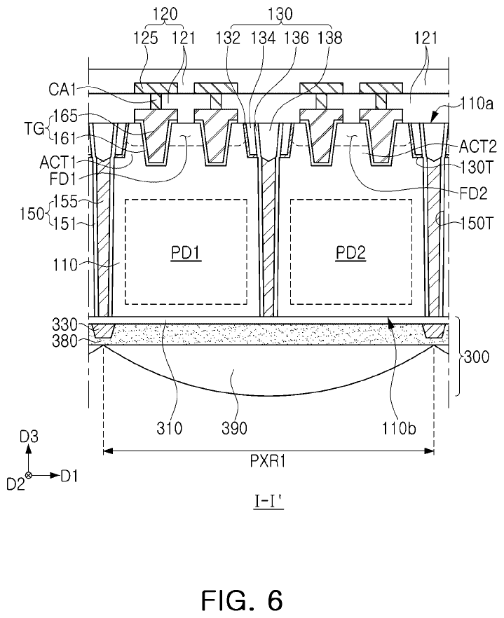

The first interconnection structure 120 may include a first inter-interconnection insulating layer 121 and a plurality of first interconnection layers 125 on the first inter-interconnection insulating layer 121. The number of layers and arrangements of interconnections constituting the first interconnection structure 120 illustrated in the drawings are merely illustrative. The plurality of first interconnection layers 125 may include interconnection patterns on different levels and contact vias electrically connecting the interconnection patterns and pixel circuit devices (see FIGS. 6 to 10). The first inter-interconnection insulating layer 121 may include at least one of, for example, silicon oxide, silicon nitride, silicon oxynitride, or a low-κ material having a lower dielectric constant than silicon oxide. The first interconnection layers 125 may include at least one of, for example, tungsten (W), copper (Cu), aluminum (Al), gold (Au), silver (Ag), or alloys thereof.

The second substrate 210 may be, similar to the first substrate 110, a bulk silicon substrate or a silicon-on-insulator (SOI) substrate. Logic circuit devices 215 may be disposed on the second substrate 210. For example, the logic circuit devices 215 may include transistors constituting a control register block, a timing generator, a lamp signal generator, a row driver, a readout circuit, a buffer, or the like.

In the second substrate structure 200, the second interconnection structure 220 may be disposed on the second substrate 210. For example, the second interconnection structure 220 may be disposed between the first interconnection structure 120 of the first substrate structure 100 and the second substrate 210.

The second interconnection structure 220 may include a second inter-interconnection insulating layer 221 and a plurality of second interconnection layers 225 on the second inter-interconnection insulating layer 221. The number of layers and arrangement of interconnections constituting the second interconnection structure 220 illustrated in the drawings are merely illustrative. The plurality of first interconnection layers 225 may include interconnection patterns on different levels and vias electrically connecting the interconnection patterns and the logic elements 215. The second inter-interconnection insulating layer 221 may include at least one of, for example, silicon oxide, silicon nitride, silicon oxynitride, and a low-κ material having a lower dielectric constant than silicon oxide. The second interconnection layers 225 may include at least one of, for example, tungsten (W), copper (Cu), aluminum (Al), gold (Au), silver (Ag), or alloys thereof.

In the present disclosure, the first interconnection structure 120 may be bonded to the second interconnection structure 220. In some implementations, a bonding insulating layer may be included on an interface between the first and second interconnection structures 120 and 220. The bonding insulating layer may include at least one of, but is not limited to, silicon oxide, silicon nitride, silicon oxynitride, or silicon carbonitride (SiCN). The second interconnection structure 220 may be bonded to the first interconnection structure 120, and at the same time, the first interconnection layer 125 and the second interconnection layer 225 may be in contact with each other. For example, the first and second interconnection structures 120 and 220 may include first and second metal pads, respectively, on a bonding interface, and the first and second metal pads may be metal bonded such that the first and second interconnection layers are electrically connected to each other.

In FIG. 3, in the pixel array region PA, the first substrate structure 100 may include a surface insulating layer 310 on the second surface 110b of the first substrate 110, a grid pattern 330 on the surface insulating layer 310, a color filter layer 380 covering the surface insulating layer 310 and the grid pattern 330, and a micro lens layer 390 on the color filter layer 380. The surface insulating layer 310, the grid pattern 330, the color filter layer 380, and the micro lens layer 390 may form the light-transmitting structure 300.

The surface insulating layer 310 may include an insulating material. For example, the surface insulating layer 310 may include at least one of silicon oxide, silicon nitride, silicon oxynitride, aluminum oxide, hafnium oxide, or a combination thereof. In some embodiments, the surface insulating layer 310 may be a multilayer. The surface insulating layer 310 may include an anti-reflection film. The anti-reflection film may prevent reflection of light incident on the first substrate 110 to improve a light receiving efficiency of the photoelectric conversion region PD. In addition, the surface insulating layer 310 may include a planarization film. The color filter layer 380 and the micro lens layer 390 described below may be formed on a uniform height. For example, the surface insulating layer 310 may include an aluminum oxide film, a hafnium oxide film, a silicon oxide film, a silicon nitride film, and a hafnium oxide film, sequentially stacked on the second surface 110b of the first substrate 110.

The color filter layer 380 may be disposed on the surface insulating layer 310. The color filter layer 380 may be arranged to correspond to each unit pixel of the pixel array region PA. The color filter layer 380 may have various color filters depending on the unit pixel. For example, the color filter layer 380 may include a red color filter, a green color filter, and a blue color filter. In some implementations, the color filter layer 380 may be disposed in a Bayer pattern. However, this is merely illustrative, and the color filter layer 380 may also include a yellow filter, a magenta filter, and a cyan filter. In some implementations, a structure having a configuration similar to the color filter layer 380 and absorbing all visible light may be disposed on the same level as the color filter layer 380.

In the present disclosure, the grid pattern 330 may be disposed between the color filter layers 380. The grid pattern 330 may be disposed on the surface insulating layer 310. The grid pattern 330 may be interposed between the color filter layers 380. In some implementations, the grid pattern 330 may be disposed to overlap the pixel isolation pattern 150 in a vertical direction D3.

In some implementations, the grid pattern 330 may include a conductive pattern and a low refractive index pattern. The conductive pattern may prevent accumulation of charges generated by ESD or the like on a surface of the first substrate 110, to effectively prevent ESD failure. The low refractive index pattern may improve a light collection efficiency to improve quality of the image sensor by refracting or reflecting light incident obliquely. For example, the conductive pattern may include at least one of titanium (Ti), titanium nitride (TiN), tantalum (Ta), tantalum nitride (TaN), tungsten (W), aluminum (Al), or copper (Cu), and the low refractive index pattern may include a low refractive index material having a lower refractive index than silicon (Si). For example, the low refractive index pattern may include at least one of silicon oxide, aluminum oxide, tantalum oxide, or a combination thereof.

The micro lens layer 390 may be disposed on the color filter layer 380. The micro lens layer 390 may include micro lenses disposed to correspond to each unit pixel of the pixel array region PA. Each of the micro lenses may have a convex shape, and may have a predetermined radius of curvature. Accordingly, the micro lenses may focus light incident on the photoelectric conversion regions PD. The micro lens layer 390 may include, for example, a light-transmitting resin. In some embodiments, the micro lens layer 390 may extend to a portion of a peripheral region (e.g., the light-blocking region OB).

In FIG. 3, the surface insulating layer 310 may extend to reach the light-blocking region OB and the pad region PR. The image sensor 10 may further include a first conductive layer 551 on the extended surface insulating layer 310, a light-blocking filter layer 380′ on the first conductive layer 551, and a protective layer 370 covering the light-blocking filter layer 380′. In some implementations, the light-blocking filter layer 380′ may extend from the first conductive layer 551 to the light-blocking region OB, and may be provided as a light-blocking structure blocking light, together with the first conductive layer 551. The light-blocking filter layer 380′ may be formed, together with the color filter layer 380, and may have substantially the same thickness as the color filter layer 380, but is not limited thereto. The light-blocking filter layer 380′ may include a blue color filter or a black filter.

In some implementations, the light-blocking region OB may be used to remove a noise signal caused by dark current. For example, in a state in which light is blocked by the first conductive layer 551 and the light-blocking filter layer 380′, the first reference region PD′ including a photodiode may be used as a reference pixel for noise removal by the photodiode. In addition, in a state in which light is blocked by the first conductive layer 551 and the light-blocking filter layer 380′, the second reference region NPD not including a photodiode may be a region for checking process noise for noise removal by other components, not the photodiode.

A first connection structure 550 and a first contact pad 391 may be disposed on the light-blocking region OB. The first connection structure 550 may include the first conductive layer 551, a first isolation pattern 553, and a first capping pattern 555. The first conductive layer 551 may cover the surface insulating layer 310 on the second surface 110b of the first substrate 110. In addition, the first conductive layer 551 may conformally cover an inner wall of a first trench T1 and an inner wall of a second trench T2. The first conductive layer 551 may penetrate the first substrate 110 and the first interconnection structure 120, i.e., the first substrate structure 100, to connect the first interconnection layer 125 and the second interconnection layer 225 to each other. In addition, the first conductive layer 551 may be connected to the pixel isolation pattern 150. The first conductive layer 551 may include a metal material (for example, tungsten). As described above, the first conductive layer 551 may block light incident into the light-blocking region OB. In some implementations, the first connection structure 550 may be omitted. For example, as described above, the first and second interconnection structures 120 and 220 may include first and second metal pads on a bonding interface, respectively, and the first and second interconnection structures 120 and 220 may be electrically connected by the first and second metal pads.

The first contact pad 391 may fill the first trench T1. The first contact pad 391 may include a metal material (for example, aluminum). The first contact pad 391 may be connected to the pixel isolation pattern 150. A bias may be applied to a filling portion 155 of the pixel isolation pattern 150 through the first contact pad 391.

A second connection structure 560 and a second contact pad 392 may be disposed on the pad region PR. The second connection structure 560 may include a second conductive layer 561, a second isolation pattern 563, and a second capping pattern 565. The second conductive layer 561 may cover the surface insulating layer 310 on the second surface 110b of the first substrate 110. The second conductive layer 561 may conformally cover an inner wall of a third trench T3 and an inner wall of a fourth trench T4. The second conductive layer 561 may penetrate the first substrate 110 and the first interconnection structure 120, i.e., the first substrate structure 100, to connect the first interconnection layer 125 and the second interconnection layer 225 to each other. The second conductive layer 561 may include a metal material (e.g., tungsten). The second conductive layer 561 may block light incident into the pad region PR.

The second contact pad 392 may fill the third trench T3. The second contact pad 392 may include a metal material (e.g., aluminum). The second contact pad 392 may serve as an electrical connection passage between the image sensor 10 and an external element. The second contact pad 392 may be connected to the logic elements (215) of the second substrate 210 through the second conductive layer 561 and the second interconnection layer 225. Electrical signals generated from the photoelectric conversion regions PD in the plurality of pixel regions PXR of the pixel array region PA may be transmitted to the external element through the first and second interconnection layers 125 and 225, the second conductive layer 561, and the second contact pad 392. In some implementations, the second contact pad 392 may be formed in the second substrate structure 200, and may be electrically connected to the external element through an external connection terminal such as a bonding wire or the like.

FIG. 4 is an enlarged view of an example of a portion of the image sensor illustrated in FIG. 2 according to some implementations. FIG. 4 may correspond to portion B of FIG. 2 according to some implementations.

In FIG. 4, a plurality of (2×2) pixel regions PXR disposed two-dimensionally are illustrated. The plurality of pixel regions PXR may be disposed in a first direction D1 and a second direction D2, parallel to a first surface 110a of a first substrate 110. A pixel isolation pattern 150 may penetrate the first substrate 110, and may be disposed between the plurality of pixel regions PXR. The pixel isolation pattern 150 may surround each of the plurality of pixel regions PXR in plan view. For example, the plurality of pixel regions PXR may include a first pixel region PXR1, a second pixel region PXR2, a third pixel region PXR3, and a fourth pixel region PXR4, and the pixel isolation pattern 150 may extend between the pixel regions PXR1, PXR2, PXR3, and PXR4. The pixel isolation pattern 150 may prevent cross-talk between neighboring pixel regions PXR. In some implementations, the pixel isolation pattern 150 may include extensions 150E extending into each of the pixel regions PXR in the second direction D2. The first extensions 150E disposed to face each other may be spaced apart from each other in the second direction D2 in each of the pixel regions PXR. For example, each of the pixel regions PXR may include photoelectric conversion regions spaced apart from each other by the extensions 150E. The photoelectric conversion regions may be neighbored to each other in the first direction D1 in each of the pixel regions PXR.

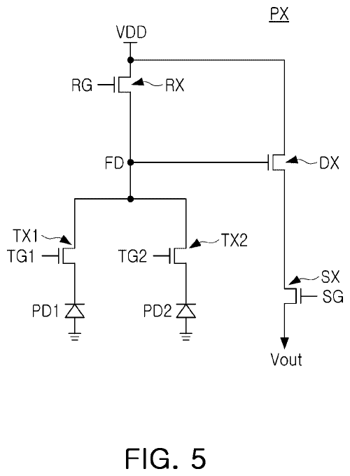

FIG. 5 is a circuit diagram of an example of a unit pixel corresponding to each of the pixel regions of FIG. 4 according to some implementations. In FIG. 5, each unit pixel PX may include pixel circuit devices, together with a first photoelectric conversion region PD1 and a second photoelectric conversion region PD2, respectively located on both side portions of a pixel region PXR. The pixel circuit devices may include a first transfer transistor TX1, a second transfer transistor TX2, and logic transistors (RX, SX, and DX). The logic transistors (RX, SX, and DX) may include a reset transistor RX, a select transistor SX, and a drive transistor DX. The first transfer transistor TX1, the second transfer transistor TX2, the reset transistor RX, and the select transistor SX may include a first transfer gate TG1, a second transfer gate TG2, a reset gate RG, and a select gate SG, respectively. The first transfer transistor TX1 and the second transfer transistor TX2 may be respectively disposed on both side portions of each pixel region PXR.

The first and second photoelectric conversion regions PD1 and PD2 may generate and accumulate photocharges in proportion to an amount of light incident from the outside. The unit pixel PX may further include a floating diffusion region FD. In the present embodiment, the floating diffusion region FD may be divided into two regions, and may be respectively disposed on both side portions of the pixel region PXR as illustrated in FIG. 4. The first transfer transistor TX1 may transfer charges generated in the first photoelectric conversion region PD1 to the floating diffusion region FD, and the second transfer transistor TX2 may transfer charges generated in the second photoelectric conversion region PD2 to the floating diffusion region FD.

The floating diffusion region FD may receive and accumulate charges generated in the first and second photoelectric conversion regions PD1 and PD2. The drive transistor DX may be controlled according to the amount of photocharges accumulated in the floating diffusion region FD. The reset transistor RX may periodically reset charges accumulated in the floating diffusion region FD. A drain electrode of the reset transistor RX may be connected to the floating diffusion region FD, and a source electrode of the reset transistor RX may be connected to a power supply voltage VDD. When the reset transistor RX is turned on, the power supply voltage VDD connected to the source electrode of the reset transistor RX may be applied to the floating diffusion region FD. Therefore, when the reset transistor RX is turned on, charges accumulated in the floating diffusion region FD may be discharged, and the floating diffusion region FD may be reset.

The drive transistor DX may act as a source follower buffer amplifier. The drive transistor DX may amplify a potential change in the floating diffusion region FD, and may output the same to an output line (Vout).

The select transistor SX may select a pixel PX to be read in units of rows. When the select transistor SX is turned on, the power supply voltage VDD may be applied to a drain electrode of the drive transistor DX. Although FIG. 5 illustrates a unit pixel region PXR having two photoelectric conversion regions PD1 and PD2 and five transistors (TX1, TX2, RX, DX, and SX), an image sensor according to the present disclosure is not limited thereto. In some implementations, the reset transistor RX, the drive transistor DX, or the select transistor SX may be shared by neighboring pixel regions PXR. Accordingly, a degree of integration of the image sensor may be improved.

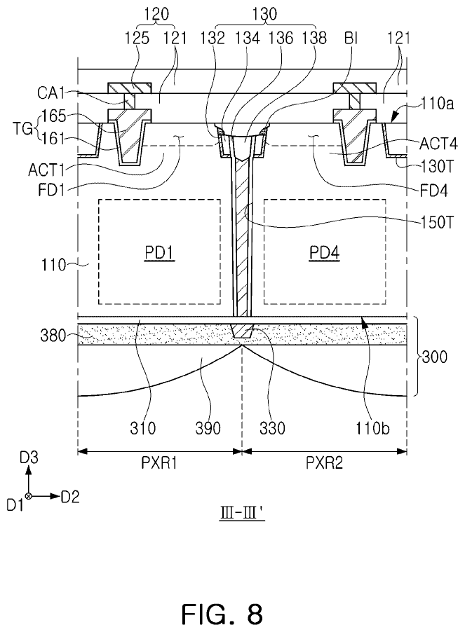

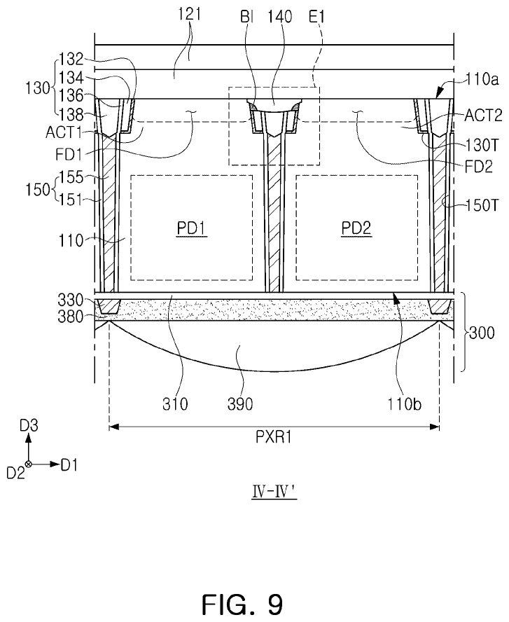

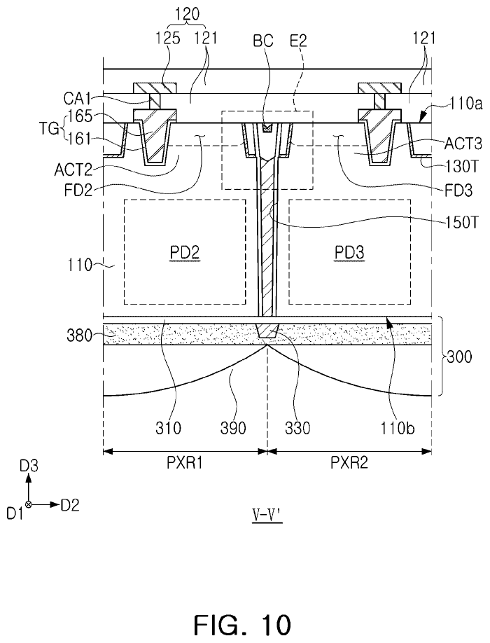

FIG. 6 is a vertical cross-sectional view taken along line I-I′ of the pixel array illustrated in FIG. 4 according to some implementations. FIG. 7 is a vertical cross-sectional view taken along line II-II′ of the pixel array illustrated in FIG. 4 according to some implementations. FIG. 8 is a vertical cross-sectional view taken along line III-III′ of the pixel array illustrated in FIG. 4 according to some implementations. FIG. 9 is a vertical cross-sectional view taken along line IV-IV′ of the pixel array illustrated in FIG. 4 according to some implementations. FIG. 10 is a vertical cross-sectional view taken along line V-V′ of the pixel array illustrated in FIG. 4 according to some implementations.

In FIGS. 6 to 10, an image sensor 10 may include a first substrate 110, a first interconnection structure 120, and a light-transmitting structure 300, as described above.

As described above, a pixel isolation pattern 150 may be disposed to surround pixel regions (PXR1, PXR2, PXR3, and PXR4), and may be formed to penetrate at least a portion of the first substrate 110. In the present disclosure, the first substrate 110 may include a pixel isolation trench 150T penetrating at least a portion of the first substrate 110, and the pixel isolation pattern 150 may be disposed in the pixel isolation trench 150T. One end of the pixel isolation pattern 150 may meet a second surface 110b of the first substrate 110, and the other end of the pixel isolation pattern 150 may be spaced from first and second surfaces 110a and 110b of the first substrate 110 in a vertical direction.

The pixel isolation pattern 150 may include an isolation insulating layer 151 on an inner wall of the pixel isolation trench 150T, and a filling portion 155 filling the isolation insulating layer 151. For example, the isolation insulating layer 151 may include silicon oxide, silicon nitride, and/or silicon oxynitride, and the filling portion 155 may include a conductive material such as a metal and a metal oxide or a conductive semiconductor material. In some implementations, the filling portion 155 may include boron-doped polycrystalline silicon.

A device isolation pattern 130 may extend from the first surface 110a of the first substrate 110 toward the second surface 110b, and may define active regions ACT. The active regions ACT may refer to a portion of the first substrate 110 disposed adjacently to the first surface 110a of the first substrate 110, and may be disposed on a vertical level, equal or similar to the device isolation pattern 130. For example, the device isolation pattern 130 may define first and second active regions ACT1 and ACT2 of a first pixel region PXR1, and may define third and fourth active regions ACT3 and ACT4 of a second pixel region PXR2. The first and second active regions ACT1 and ACT2 may be spaced apart from each other in the first direction D1 with the device isolation pattern 130 and the pixel isolation pattern 150 therebetween, and the third and fourth active regions ACT3 and ACT4 may be spaced apart from each other in the first direction D1 with the device isolation pattern 130 and the pixel isolation pattern 150 therebetween.

Each pixel region PXR may further include a ground region GR, and the ground region GR may be defined by the device isolation pattern 130, and may be disposed between the active regions ACT. The ground region GR may be spaced apart from the active regions ACT, and may be a region doped with an impurity of the same conductivity type (e.g., P type) as the first substrate 110.

In some implementations, the first substrate 110 may include a device isolation trench 130T penetrating at least a portion of the first substrate 110, and the device isolation pattern 130 may be disposed in the device isolation trench 130T. One end of the device isolation pattern 130 may meet the first surface 110a of the first substrate 110, and the other end of the device isolation pattern 130 may be spaced from the first and second surfaces 110a and 110b of the first substrate 110 in the vertical direction. The device isolation trench 130T may be connected to the pixel isolation trench 150T, and the pixel isolation pattern 150 may be connected to the device isolation pattern 130. In the present embodiment, the device isolation pattern 130 may be disposed on the pixel isolation pattern 150.

The device isolation pattern 130 may include an isolation liner 132, a first isolation insulating layer 134, a second isolation insulating layer 136, and a third isolation insulating layer 138. The isolation liner 132 may cover an inner wall of the device isolation trench 130T, and the first isolation insulating layer 134 may be disposed on the isolation liner 132. The second isolation insulating layer 136 may be disposed on the first isolation insulating layer 134, and may extend in the vertical direction to be connected to the isolation insulating layer 151 of the pixel isolation pattern 150. For example, the second isolation insulating layer 136 may include the same material as the isolation insulating layer 151, and may have an integrated structure. The second isolation insulating layer 136 may be disposed in a region in which the device isolation pattern 130 overlaps the pixel isolation pattern 150 in the vertical direction, and may not be disposed in a region in which the device isolation pattern 130 does not vertically overlap the pixel isolation pattern 150 in the vertical direction. For example, the second isolation insulating layers 136 may form a pair, and may extend in the horizontal direction (D1 and D2) along the pixel isolation pattern 150. The third isolation insulating layer 138 may be disposed on the second isolation insulating layers 136, and may cover the filling portion 155. The third isolation insulating layer 138 may be disposed in a region in which the device isolation pattern 130 overlaps the pixel isolation pattern 150 in the vertical direction, and may not be disposed in a region in which the device isolation pattern 130 does not overlap the pixel isolation pattern 150 in the vertical direction.

The isolation liner 132, the first isolation insulating layer 134, the second isolation insulating layer 136, and the third isolation insulating layer 138 may include silicon oxide, silicon nitride, and/or silicon oxynitride. In an embodiment, the first isolation insulating layer 134, the second isolation insulating layer 136, and the third isolation insulating layer 138 may include the same material as the isolation insulating layer 151, and may have a structure integral with the isolation insulating layer 151.

In FIGS. 4 and 6 to 10, a vertical transfer gate TG, a floating diffusion region FD, and a pixel gate PG for other pixel circuit devices (also referred to as “logic transistors”) may be disposed in each pixel region PXR, and may be disposed adjacently to the first surface 110a of the first substrate 110.

The vertical transfer gate TG and the floating diffusion region FD may be disposed on the active region ACT. A photoelectric conversion region PD may extend in a second direction D2 in the pixel region PXR, and the vertical transfer gate TG and the floating diffusion region FD may be disposed to overlap in a direction, perpendicular to the photoelectric conversion region PD (e.g., D3). The floating diffusion region FD may be disposed adjacently to the first surface 110a of the first substrate 110. The vertical transfer gate TG may be disposed adjacently to the floating diffusion region FD. In some implementations, the photoelectric conversion region PD and the floating diffusion region FD may be regions doped with impurities of a different conductivity type (e.g., N-type impurities) than a conductivity type (e.g., P-type) of the first substrate 110.

In some implementations, a first pixel region PXR1 may include a first photoelectric conversion region PD1 and a first floating diffusion region FD1, vertically overlapping the first active region ACT1, and may include a second photoelectric conversion region PD2 and a second floating diffusion region FD2, vertically overlapping the second active region ACT2. The first photoelectric conversion region PD1 and the first floating diffusion region FD1 may be spaced apart from the second photoelectric conversion region PD2 and the second floating diffusion region FD2 in the first direction D1, respectively, with the device isolation pattern 130 and the pixel isolation pattern 150 interposed therebetween.

A second pixel region PXR2 may include a third photoelectric conversion region PD3 and a third floating diffusion region FD3, vertically overlapping the third active region ACT3, and may include a fourth photoelectric conversion region PD4 and a fourth floating diffusion region FD4, vertically overlapping the fourth active region ACT4. The third photoelectric conversion region PD3 and the third floating diffusion region FD3 may be spaced apart from the fourth photoelectric conversion region PD4 and the fourth floating diffusion region FD4 in the first direction D1, respectively, with the device isolation pattern 130 and the pixel isolation pattern 150 therebetween.

The vertical transfer gates TG may be disposed adjacently to the floating diffusion region FD corresponding thereto. In some implementations, each pixel region PXR may have two vertical transfer gates TG disposed adjacently to each floating diffusion region FD. For example, the first pixel region PXR1 may have two vertical transfer gates TG disposed adjacently to the first floating diffusion region FD1, and two vertical transfer gates TG disposed adjacently to the second floating diffusion region FD2.

Upper portions of the vertical transfer gates TG may be disposed on the first surface 110a of the first substrate 110, and lower portions of the vertical transfer gates TG may extend into the first substrate 110 toward the photoelectric conversion region PD corresponding thereto. The vertical transfer gate TG may include a first gate electrode portion 165 and a first gate dielectric layer 161 between the first gate electrode portion 165 and the first substrate 110. The first gate electrode portion 165 may include polycrystalline silicon, and the first gate dielectric layer 161 may include silicon oxide, silicon nitride, or a ferroelectric material.

In some implementations, each pixel region PXR may include a pixel gate PG disposed on the active region ACT and a pair of source/drain regions SD adjacent to the pixel gate PG. The pixel gate PG may, together with the source/drain regions SD, form at least one logic transistor (RX, SX, or DX) on the first surface 110a of the first substrate 110. The at least one of the logic transistor (RX, SX, or DX) may include a reset transistor RX, a select transistor SX, and a drive transistor DX.

In each pixel region PXR, the pixel gate PG and the source/drain regions SD may overlap the photoelectric conversion region PD in a direction, perpendicular to the photoelectric conversion region PD (e.g., D3), and may be spaced apart from the floating diffusion region FD and the vertical transfer gates TG in the second direction D2. For example, in the first pixel region PXR1, the pixel gates PG may be disposed on the first and second active regions ACT1 and ACT2, respectively, and spaced apart from the first and second floating diffusion regions FD1 and FD2 in the second direction D2.

The pixel gate PG may include a second gate electrode portion 185 and a second gate insulating layer 181 between the second gate electrode portion 185 and the first substrate 110. The second gate electrode portion 185 may include polycrystalline silicon, and the second gate insulating layer 181 may include silicon oxide, silicon nitride, or a ferroelectric material. In an embodiment, the source/drain regions SD may be regions doped with an impurity of a second conductivity type (e.g., an N-type impurity), different from a conductivity type (e.g., a P-type) of the first substrate 110.

Although the image sensor 10 illustrated in FIG. 4 is illustrated as having only two pixel gates PG in each pixel region PXR, the pixel gates PG described above may all be introduced as gate electrodes for the reset transistor RX, the select transistor SX, and the drive transistor DX.

The first interconnection structure 120 may be disposed on the first surface 110a of the first substrate 110, and may cover the vertical transfer gates TG and the pixel gates PG. The first interconnection structure 120 may include a first inter-interconnection insulating layer 121 and first interconnection layers 125 on the first inter-interconnection insulating layer 121.

The vertical transfer gate TG may be electrically connected to the first interconnection layer 125 of the first interconnection structure 120. The first interconnection structure 120 may further include a contact via CA1 electrically connecting the vertical transfer gate TG to the first interconnection layer 125. The pixel gate PG may be electrically connected to the first interconnection layer 125 of the first interconnection structure 120. The first interconnection structure 120 may further include a contact via CA1 electrically connecting the pixel gate PG to the first interconnection layer 125. Similarly, the first interconnection structure 120 may further include contact vias connecting the source/drain regions SD and the ground regions GR.

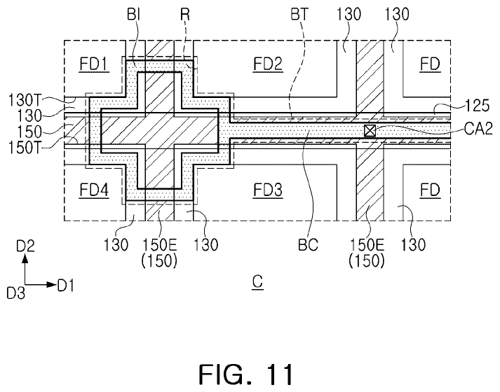

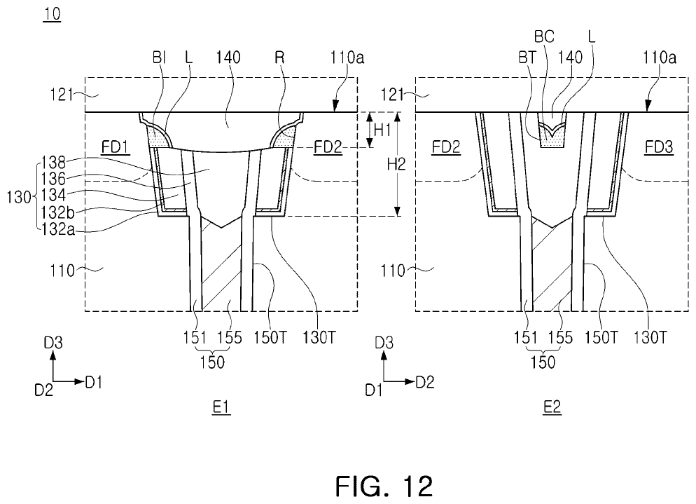

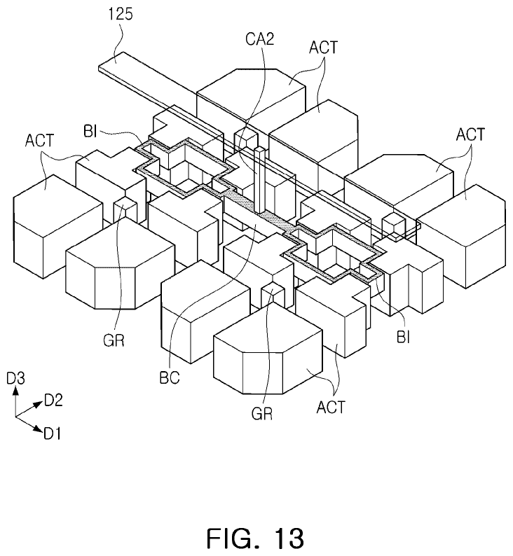

FIG. 11 is a partial enlarged view of the pixel array illustrated in FIG. 10 according to some implementations. FIG. 11 may correspond to portion C of FIG. 10 according to some implementations. FIG. 12 is a partial enlarged view of FIGS. 9 and 10 according to some implementations. FIG. 12 may correspond to portion E1 of FIG. 9 and portion E2 of FIG. 10. FIG. 13 is a perspective view illustrating examples of a buried interconnection portion and a buried conductive line according to some implementations.

In FIGS. 11 to 13, an image sensor 10 may include buried interconnection portions BI electrically connecting floating diffusion regions FD, and buried conductive lines BC electrically connecting the buried interconnection portions BI. For example, a first substrate 110 may include a recess region R and a trench BT, formed in a first surface 110a, and a buried interconnection portion BI and a buried conductive line BC may be disposed in the recess region R and the trench BT, respectively.

The recess region R may be formed on a device isolation pattern 130, and may expose four adjacent floating diffusion regions FD. For example, in FIG. 11, the recess region R may expose side surfaces of first to fourth floating diffusion regions FD1, FD2, FD3, and FD4. The exposed side surfaces of the first to fourth floating diffusion regions FD1, FD2, FD3, and FD4, and an upper surface of the device isolation pattern 130 may define the recess region R. The buried interconnection portion BI may extend along a sidewall of the recess region R, and may be disposed on the device isolation pattern 130. For example, the upper surface of the device isolation pattern 130 in the recess region R may be spaced apart from the first surface 110a of the first substrate 110, and may be located farther from the first surface 110a than upper surfaces of the floating diffusion regions FD. The buried interconnection portion BI may be in contact with the exposed side surfaces of the first to fourth floating diffusion regions FD1, FD2, FD3, and FD4 and the upper surface of the device isolation pattern 130. In some implementations, the buried interconnection portion BI is illustrated as being in contact with an isolation liner 132 and a first isolation insulating layer 134 of the device isolation pattern 130, but the present disclosure is not limited thereto. According to some implementations, the buried interconnection portion BI may also be in contact with a second isolation insulating layer 136 and a third isolation insulating layer 138 of the device isolation pattern 130. In some implementations, the isolation liner 132 may include a first isolation liner 132a and a second isolation liner 132b on the first isolation liner 132a. For example, the first isolation liner 132a may include silicon oxide, and the second isolation liner 132b may include silicon nitride.

In this case, an “upper surface” or a “lower surface” of a component may mean the upper surface or the lower surface of the component, based on the drawings illustrated in FIGS. 6 to 10 and FIG. 12, respectively.

In plan view, the buried interconnection portion BI may extend along the sidewall of the recess region R in the horizontal direction. The buried interconnection portion BI may extend along an edge of the recess region R, and the buried interconnection portion BI may not be disposed in a central portion of the recess region R. For example, the buried interconnection portion BI may have a closed loop shape.

The trench BT may be formed on the device isolation pattern 130, and may not expose the floating diffusion regions FD. For example, the trench BT may extend in the second direction D2 between the second and third floating diffusion regions FD2 and FD3. The trench BT is illustrated as being formed in the third isolation insulating layer 138 of the device isolation pattern 130, but the present disclosure is not limited thereto. According to some implementations, the trench BT may extend onto the first isolation insulating layer 134 and the second isolation insulating layer 136 of the device isolation pattern 130. In some implementations, the buried conductive line BC may fill a lower portion of the trench BT. For example, the buried conductive line BC may be in contact with sidewalls and a lower surface of the trench BT, and may extend in the second direction D2. A lower end and an upper end of the buried conductive line BC may be disposed on the same level as a lower end and an upper end of the buried interconnection portion BI, respectively, but are not limited thereto. In some implementations, the upper end of the buried conductive line BC and the upper end of the buried interconnection portion BI may be spaced apart from the first surface 110a of the first substrate 110. An upper surface of the buried conductive line BC may not be parallel to the first surface 110a of the first substrate 110. For example, a vertical width of the buried conductive line BC may increase toward the floating diffusion regions (FD2 and FD3). In some implementations, a ratio of a height H1 of the recess region R to a height H2 of the trench BT may be 1:3.33 to 1:8.33. In some implementations, a horizontal width of the buried interconnection portion BI along at least the first direction D1 may increase as a direction from the first surface 110a of the first substrate 110.

In plan view, the buried conductive line BC may be connected to the buried interconnection portion BI having a closed loop shape. For example, the buried interconnection portions BI may be spaced apart from each other in the second direction D2, and the buried conductive line BC may electrically connect the buried interconnection portions BI to each other between the buried interconnection portions BI. The buried interconnection portion BI and the buried conductive line BC may include the same material, and may have an integrated structure. The buried interconnection portion BI and the buried conductive line BC may include polycrystalline silicon.

The image sensor 10 may further include a liner layer L and a gapfill insulating layer 140, covering the buried interconnection portion BI and the buried conductive line BC. The liner layer L may cover an upper surface of the buried interconnection portion BI, and may cover a side surface of the floating diffusion region FD exposed by the recess region R. For example, the liner layer L may extend between the buried interconnection portion BI and the gapfill insulating layer 140 and between the side surface of the floating diffusion region FD and the gapfill insulating layer 140. The liner layer L may also cover the upper surface of the buried conductive line BC. The liner layer L may extend between the buried conductive line BC and the gapfill insulating layer 140.

The gapfill insulating layer 140 may cover the liner layer L and the device isolation pattern 130, and may completely fill an internal space of the recess region R and an internal space of the trench BT. The liner layer L and the gapfill insulating layer 140 may include silicon oxide. Since the liner layer L has different properties such as density or the like from the gapfill insulating layer 140, a boundary between the liner layer L and the gapfill insulating layer 140 may be observed.

According to some implementations, the buried interconnection portion BI and the buried conductive line BC, electrically connecting the floating diffusion regions FD, may be buried in the first substrate 110. Accordingly, as compared to a case in which a contact via and an interconnection layer are formed on each of the floating diffusion regions FD, a degree of freedom in designing the vertical transfer gates TG, the pixel gates PG, and the first interconnection layers 125 may increase. In addition, when the contact via is formed on the floating diffusion regions FD, parasitic capacitance may occur between the contact vias and the vertical transfer gates TG and the pixel gates PG, but according to some implementations, since the buried interconnection portions BI may be in direct contact with the floating diffusion regions FD, the parasitic capacitance may be eliminated or reduced. Accordingly, a conversion efficiency of light received in each pixel region PXR, converted into an electric signal, and transmitted to the first interconnection structure 120 may increase. In addition, since the buried interconnection portions BI and the buried conductive lines BC are formed to be self-aligned along the inner wall of the recess region R and the inner wall of the trench T, the manufacturing process may be simplified, and a more highly integrated and miniaturized image sensor 10 may be implemented.

FIG. 13 is a perspective view illustrating examples of a buried interconnection portion and a buried conductive line according to some implementations. In FIGS. 11 and 13, an image sensor 10 may further include a contact via CA2 connected to a buried conductive line BC. The contact via CA2 may be in contact with an upper surface of the buried conductive line BC, and may extend in the vertical direction. Since the upper surface of the buried conductive line BC is buried in a first substrate 110, a portion of the contact via CA2 may be buried in the first substrate 110. The contact via CA2 may be electrically connected to a first interconnection structure 120. For example, floating diffusion regions FD may be electrically connected to a first interconnection layer 125 via a buried interconnection portions BI, the buried conductive line BC, and the contact vias CA2.

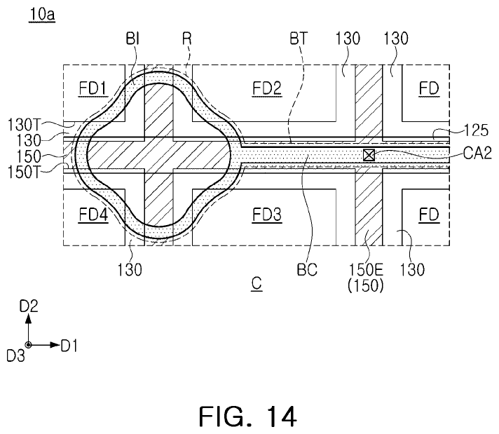

FIG. 14 is a plan view of an example of an image sensor according to some implementations. In FIG. 14, an image sensor 10a may include buried interconnection portions BI electrically connecting floating diffusion regions FD1, FD2, FD3, and FD4. In some implementations, the buried interconnection portions BI may be rounded when viewed in plan view. A recess region R may also have a closed curve shape to surround the buried interconnection portions BI.

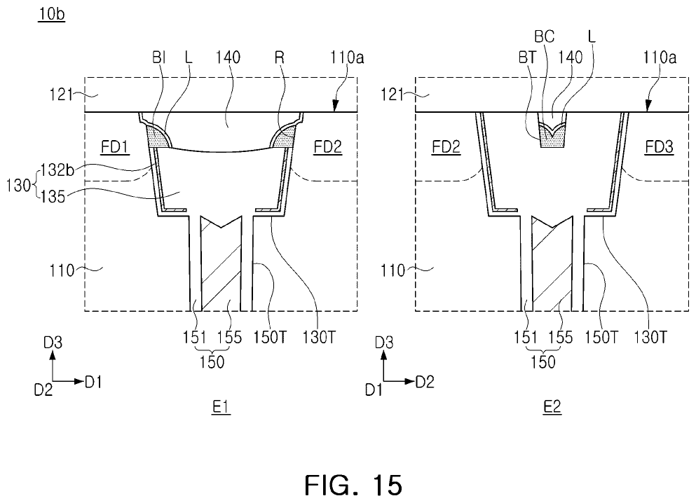

FIGS. 15 to 18 are vertical cross-sectional views of an example of an image sensor according to some implementations. In FIG. 15, an image sensor 10b may include a buried interconnection portion BI and a buried conductive line BC on a device isolation pattern 130. In a structure of the image sensor 10 illustrated in FIG. 12, the first isolation liner 132a, the first isolation insulating layer 134, the second isolation insulating layer 136, and the third isolation insulating layer 138 may include the same material, and the interface therebetween may not be observed. The first isolation liner 132a, the first isolation insulating layer 134, the second isolation insulating layer 136, and the third isolation insulating layer 138 may be referred to as an isolation insulating layer 135. In some implementations, the isolation insulating layer 135 and an isolation insulating layer 151 may include the same material, and an interface therebetween may not be observed.

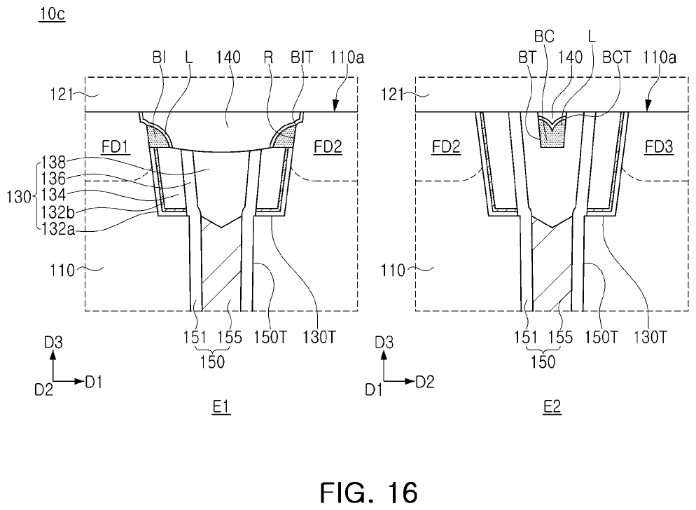

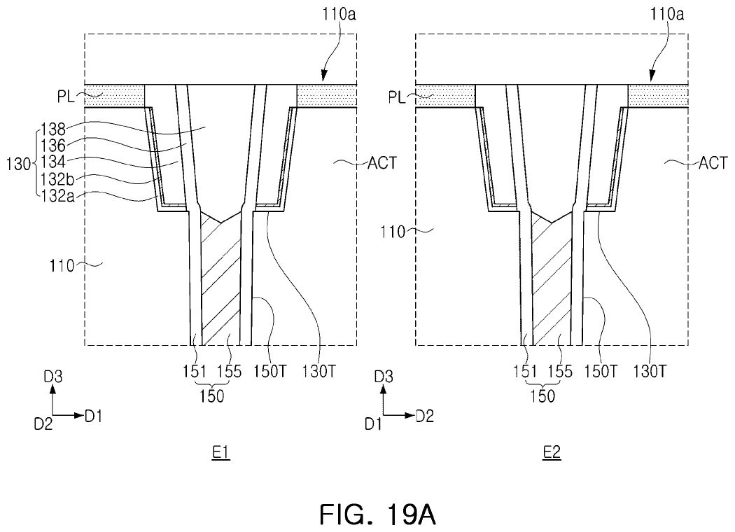

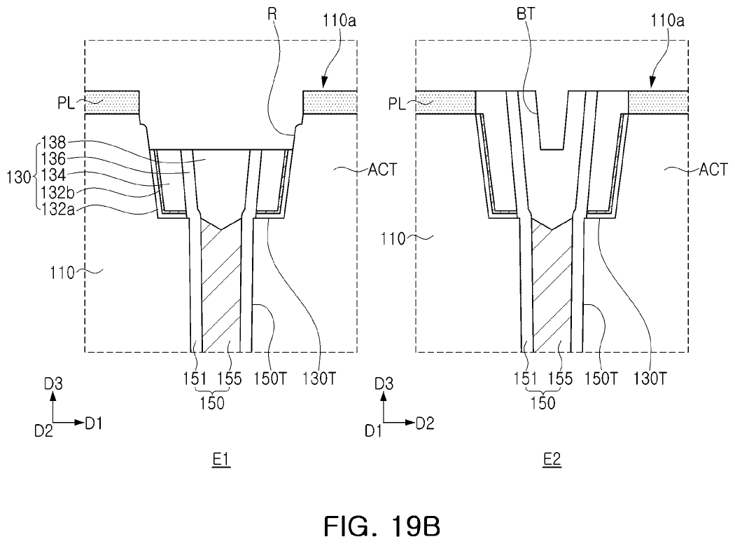

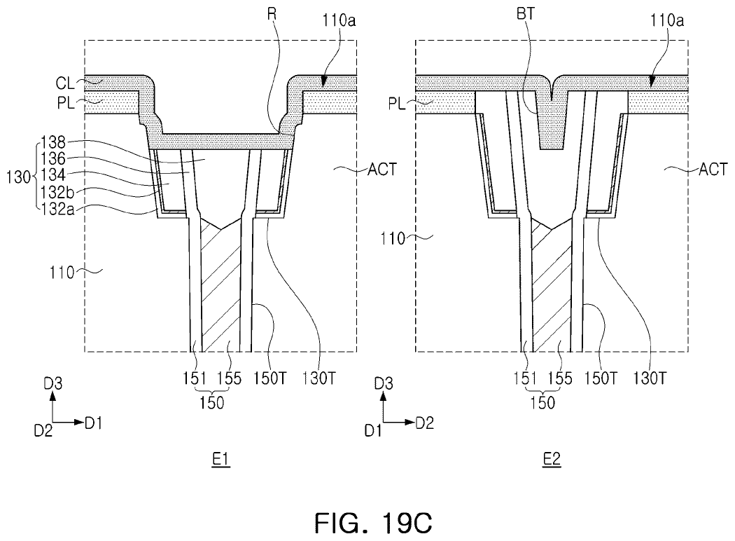

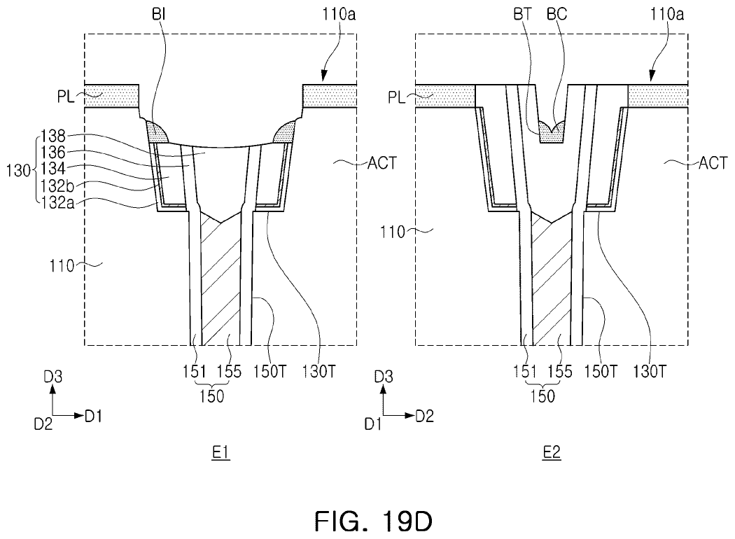

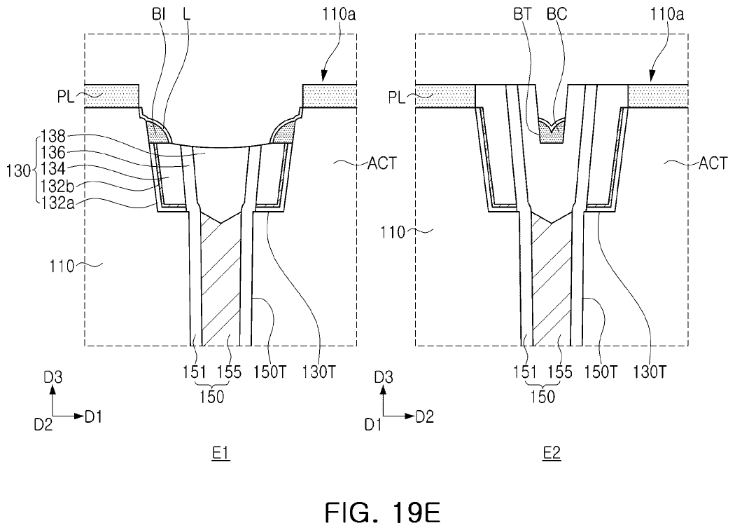

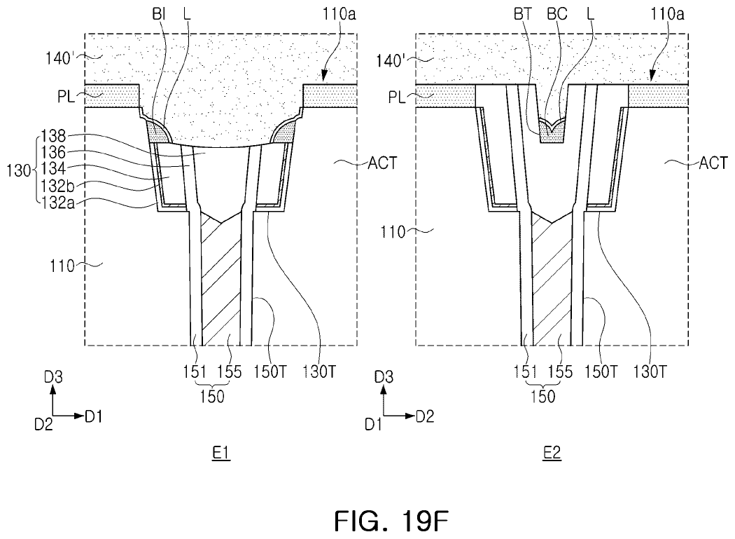

In FIG. 16, an image sensor 10c may include a buried interconnection portion BI and a buried conductive line BC on a device isolation pattern 130. In some implementations, an upper end BCT of the buried conductive line BC may be disposed on a higher level than an upper end BIT of the buried interconnection portion BI. In an etch-back process described below with reference to FIG. 19D, a conductive material layer CL in a trench BT may be etched relatively less, and thus the upper end BCT of the buried conductive line BC may be formed on a relatively higher level. For example, the upper end BCT of the buried conductive line BC may be closer to a first surface 110a of the first substrate 110 than the upper end BIT of the buried interconnection portion BI. In some implementations, a vertical width of the buried conductive line BC may be greater than a vertical width of the buried interconnection portion BI. For example, a lower surface of the buried conductive line BC may be located on the same level as a lower surface of the buried interconnection portion BI.

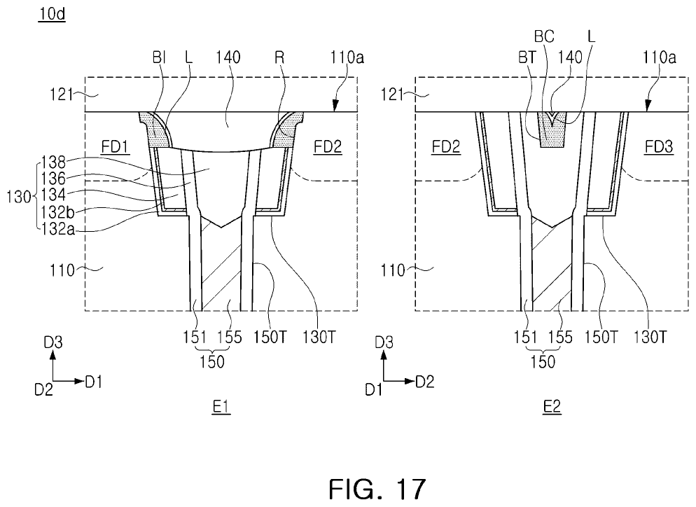

In FIG. 17, an image sensor 10d may include a buried interconnection portion BI and a buried conductive line BC on a device isolation pattern 130. In some implementations, an upper surface of the buried interconnection portion BI may be coplanar with an upper surface of a gapfill insulating layer 140. For example, the buried interconnection portion BI may completely cover side surfaces of a floating diffusion regions FD exposed by a recess region R, and the upper surface of the buried interconnection portion BI may be exposed without being covered by the gapfill insulating layer 140 and a liner layer L.

In some implementations, an upper surface of the buried conductive line BC may be coplanar with the upper surface of the gapfill insulating layer 140. For example, the upper surface of the buried conductive line BC may be exposed without being covered by the gapfill insulating layer 140 and the liner layer L. In some implementations, an upper surface of the liner layer L may also be coplanar with the upper surface of the gapfill insulating layer 140.

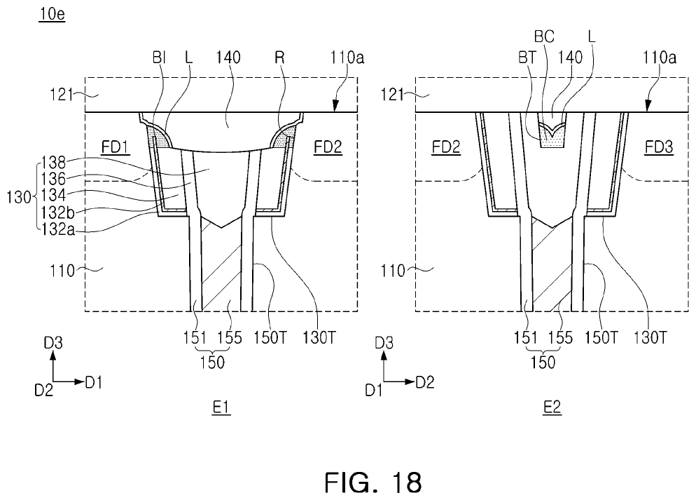

In FIG. 18, an image sensor 10e may include a buried interconnection portion BI and a buried conductive line BC on a device isolation pattern 130. In some implementations, a second isolation liner 132b of the device isolation pattern 130 may protrude in a vertical direction from an upper surface of a first isolation liner 132a, an upper surface of a first isolation insulating layer 134, an upper surface of a second isolation insulating layer 136, and an upper surface of a third isolation insulating layer 138. In an embodiment, the second isolation liner 132b may include a material having etch selectivity with respect to the first isolation liner 132a, the first isolation insulating layer 134, the second isolation insulating layer 136, and the third isolation insulating layer 138. Accordingly, in an anisotropic etching process and a cleaning process, described below with reference to FIGS. 19B and 19C, the second isolation liner 132b may be etched relatively less than the first isolation liner 132a, the first isolation insulating layer 134, the second isolation insulating layer 136, and the third isolation insulating layer 138. For example, an upper end of the second isolation liner 132b may be closer to a first surface 110a of a first substrate 110 than the upper surface of the first isolation liner 132a, the upper surface of the first isolation insulating layer 134, the upper surface of the second isolation insulating layer 136, and the upper surface of the third isolation insulating layer 138. A portion of the second isolation liner 132b may extend into the buried interconnection portion BI.

FIGS. 19A to 19F are cross-sectional views of processes illustrating an example of a method of manufacturing an image sensor according to some implementations. FIGS. 19A to 19F may correspond to portion E1 of FIG. 9 and portion E2 of FIG. 10, respectively.

In FIG. 19A, a device isolation pattern 130 and a pixel isolation pattern 150 may be formed in a first substrate 110. First, a protective layer PL covering a first surface 110a of the first substrate 110 may be formed. A device isolation trench 130T may be formed in the first surface 110a, and insulating material layers may be filled in the device isolation trench 130T to form the device isolation pattern 130. The device isolation pattern 130 and the first substrate 110 may be anisotropically etched to form a pixel isolation trench 150T, and the pixel isolation trench 150T may be filled with an insulating material layer and a conductive material layer to form the pixel isolation pattern 150. Active regions ACT of the device isolation pattern 130 may be defined, and the pixel isolation pattern 150 may define a pixel region PXR.

The device isolation pattern 130 may include an isolation liner 132, a first isolation insulating layer 134, a second isolation insulating layer 136, and a third isolation insulating layer 138. The pixel isolation pattern 150 may include an isolation insulating layer 151 on an inner wall of a pixel isolation trench T2, and a filling portion 155 filling an isolation insulating layer 151.

In FIG. 19B, a recess region R and a trench BT may be formed by etching the device isolation pattern 130. The recess region R may be formed in a region in which floating diffusion regions FD, as described above with reference to FIG. 4, are formed, and may expose side surfaces of the active regions ACT. The trench BT may extend in the second direction D2, and may connect recess regions R. In some implementations, the first surface 110a of the first substrate 110 may be partially etched by an etching process.

In FIG. 19C, a conductive material layer CL may be formed. The conductive material layer CL may cover the protective layer PL, the recess region R, and the trench BT. The conductive material layer CL may conformally cover the recess region R, and may completely fill the trench BT. The conductive material layer CL may include doped polycrystalline silicon. In an embodiment, before forming the conductive material layer CL, a cleaning process may be further performed to remove a natural oxide film formed on the active regions ACT.

In FIG. 19D, the conductive material layer CL may be etched back to form a buried interconnection portion BI and a buried conductive line BC. In some implementations, an upper end of the buried interconnection portion BI and an upper end of the buried conductive line BC may be spaced apart from the first surface 110a of the first substrate 110, but are not limited thereto.

In FIG. 19E, a liner layer L may be formed on the buried interconnection portion BI and the buried conductive line BC. For example, an oxidation process may be performed to form an oxide film on a surface of the buried interconnection portion BI and a surface of the buried conductive line BC, thereby forming the liner layer L. The liner layer L may also be formed on the side surfaces of the active regions ACT exposed by the recess region R. The liner layer L may cover the active regions ACT, the buried interconnection portions BI, and the buried conductive lines BC, and may protect them and prevent electrical characteristics of the image sensor 10 from being deteriorated. In some implementations, a cleaning process may be further performed before forming the liner layer L.

In FIG. 19F, an insulating material layer 140′ may be formed. The insulating material layer 140′ may completely fill the recess region R and the trench BT, and may cover the protective layer PL. The insulating material layer 140′ may include silicon oxide.

In FIGS. 6 to 12, a gapfill insulating layer 140 may be formed by flattening the insulating material layer 140′ to fill the recess region R and the trench BT. The gapfill insulating layer 140 may be buried in the first substrate 110, and may cover the buried interconnection portion BI and the buried conductive line BC. Thereafter, floating diffusion regions FD may be formed in the active regions ACT, and transfer gates TG, pixel gates PG, and first interconnection structures 120 may be formed on the first surface 110a of the first substrate 110, thereby manufacturing the image sensor 10.

According to some implementations, a buried interconnection portion electrically connecting floating diffusion regions may be buried in a first substrate, such that a degree of design freedom of vertical transfer gates, pixel gates, and first interconnection layers may increase. Since the buried interconnection portion is in direct contact with the floating diffusion regions, conversion efficiency of light received in the pixel region, converted into an electric signal, and transmitted to an interconnection structure may increase.

While this disclosure contains many specific implementation details, these should not be construed as limitations on the scope of what may be claimed, equivalents thereof, as well as claims to be described later. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An image sensor comprising:
a semiconductor substrate having a first surface and a second surface that is on an opposite side of the semiconductor substrate from the first surface;
a pixel isolation pattern in the semiconductor substrate and defining a first pixel region and a second pixel region, wherein the first pixel region includes a first photoelectric conversion region and a second photoelectric conversion region that are spaced apart from each other in a first horizontal direction;
a device isolation pattern on the first surface of the semiconductor substrate, wherein the device isolation pattern defines a plurality of active regions;
a plurality of floating diffusion regions adjacent to the first surface of the semiconductor substrate, the plurality of floating diffusion regions include a first floating diffusion region and a second floating diffusion region overlapping the first photoelectric conversion region and the second photoelectric conversion region, respectively, in a vertical direction; and
a buried interconnection portion buried in the semiconductor substrate and electrically connecting the first floating diffusion region to the second floating diffusion region.

2. The image sensor of claim 1, wherein the buried interconnection portion contacts an upper surface of the device isolation pattern the first floating diffusion region, and the second floating diffusion region.

3. The image sensor of claim 1, wherein a horizontal width of the buried interconnection portion increases as a distance from the first surface of the semiconductor substrate increases.

4. The image sensor of claim 1, wherein an upper end of the buried interconnection portion is below the first surface of the semiconductor substrate.

5. The image sensor of claim 1, comprising a gapfill insulating layer on the buried interconnection portion and buried in the semiconductor substrate.

6. The image sensor of claim 5, comprising a liner between the buried interconnection portion and the gapfill insulating layer.

7. The image sensor of claim 5, wherein an upper surface of the buried interconnection portion is coplanar with an upper surface of the gapfill insulating layer.

8. The image sensor of claim 1,
wherein the second pixel region is spaced apart from the first pixel region in a second horizontal direction that intersects the first horizontal direction,
wherein the image sensor includes a buried conductive line buried in the semiconductor substrate and electrically connected to the buried interconnection portion, and
wherein the buried conductive line extends in the first horizontal direction between the first pixel region and the second pixel region.

9. The image sensor of claim 8, wherein the buried conductive line contacts an upper surface of the device isolation pattern.

10. The image sensor of claim 8, wherein the buried conductive line is spaced apart from the first floating diffusion region and from the second floating diffusion region.

11. The image sensor of claim 8, wherein a vertical width of the buried conductive line increases toward the plurality of floating diffusion regions.

12. The image sensor of claim 8,
wherein the buried conductive line and the buried interconnection portion comprise a same material, and
wherein the buried conductive line and the buried interconnection portion are integral.

13. The image sensor of claim 8, wherein an upper end of the buried conductive line is closer to the first surface of the semiconductor substrate than an upper end of the buried interconnection portion.

14. The image sensor of claim 1,
wherein the second pixel region includes a third photoelectric conversion region in the semiconductor substrate,
wherein the plurality of floating diffusion regions include a third floating diffusion region overlapping the third photoelectric conversion region in the vertical direction, and
wherein the buried interconnection portion electrically connects the second floating diffusion region and the third floating diffusion region.

15. An image sensor comprising:
a semiconductor substrate having a first surface and a second surface that is on an opposite side of the semiconductor substrate from the first surface;
a pixel isolation pattern in the semiconductor substrate and defining pixel regions, wherein the pixel regions include photoelectric conversion regions in the semiconductor substrate;
a device isolation pattern on the first surface of the semiconductor substrate, wherein the device isolation pattern defines active regions;
a plurality of floating diffusion regions adjacent to the first surface of the semiconductor substrate and overlapping the photoelectric conversion regions in a vertical direction; and
a first buried interconnection portion electrically connecting adjacent floating diffusion regions of the plurality of floating diffusion regions,
wherein the semiconductor substrate includes a first recess region in the first surface, wherein the first recess region exposes the floating diffusion regions,
wherein the first buried interconnection portion extends in the first recess region in a horizontal direction, and
wherein the first buried interconnection portion electrically connects the floating diffusion regions.

16. The image sensor of claim 15, wherein, in plan view of the image sensor, the first buried interconnection portion has a closed loop shape.

17. The image sensor of claim 15, comprising a buried conductive line in a trench of the first surface of the semiconductor substrate and extending between two adjacent pixel regions among the pixel regions in the horizontal direction,
wherein the buried conductive line is electrically connected to the first buried interconnection portion.

18. The image sensor of claim 17, comprising:
a contact via connected to the buried conductive line and extending in the vertical direction; and
a portion of the contact via is buried in the semiconductor substrate.

19. The image sensor of claim 17, comprising a second buried interconnection portion in a second recess region of the first surface of the semiconductor substrate,
wherein the second buried interconnection portion electrically connects adjacent floating diffusion regions of the plurality of floating diffusion regions, and
wherein the buried conductive line electrically connects the first buried interconnection portion to the second buried interconnection portion.

20. An image sensor comprising:
a semiconductor substrate having a first surface and a second surface that is on an opposite side of the semiconductor substrate from the first surface;
a pixel isolation pattern in the semiconductor substrate and defining first to fourth pixel regions, wherein the first to fourth pixel regions include photoelectric conversion regions disposed in the semiconductor substrate;
a device isolation pattern on the first surface of the semiconductor substrate, wherein the device isolation pattern defines active regions;
a plurality of floating diffusion regions adjacent to the first surface of the semiconductor substrate and overlapping the photoelectric conversion regions in a vertical direction;
a first buried interconnection portion electrically connecting a first group of adjacent floating diffusion regions of the plurality of floating diffusion regions;
a second buried interconnection portion electrically connecting a second group of adjacent floating diffusion regions of the plurality of floating diffusion regions, wherein the second buried interconnection portion is spaced apart from the first buried interconnection portion in a first horizontal direction; and
a buried conductive line electrically connecting the first buried interconnection portion to the second buried interconnection portion, wherein the buried conductive line extends in the first horizontal direction,
wherein the first buried interconnection portion is between the first pixel region and the second pixel region, wherein the first pixel region and the second pixel region are spaced apart from each other in a second horizontal direction that intersects the first horizontal direction,
wherein the second buried interconnection portion is between the third pixel region and the fourth pixel region, and wherein the third pixel region and the fourth pixel region are spaced apart from the first pixel region and the second pixel region in the first horizontal direction.
